(19) United States
(12) Patent Application Publication
(10) Pub. No.: US 2014/0305502 A1
(43) Pub. Date: Oct. 16, 2014

(54) GLASS SUBSTRATE AND METHOD FOR PRODUCING GLASS SUBSTRATE

(71) Applicant: Asahi Glass Company, Limited, Tokyo (JP)

(72) Inventors: Jun SASAI, Tokyo (JP); Yuki KONDO, Tokyo (JP); Yo NAKAHARA, Tokyo (JP); Kuniaki HIROMATSU, Tokyo (JP); Hideaki HAYASHI, Tokyo (JP)

(73) Assignee: Asahi Glass Company, Limited, Tokyo (JP)

(21) Appl. No.: 14/318,017

(22) Filed: Jun. 27, 2014

Related U.S. Application Data
(63) Continuation of application No. PCT/JP2012/083117, filed on Dec. 20, 2012.

(30) Foreign Application Priority Data
Dec. 27, 2011 (JP) 2011-286738

(51) Int. Cl. C03B 18/18; C03C 4/00; H01L 31/0224

(52) U.S. Cl. CPC C03B 18/18; H01L 31/022466; C03C 4/0085
USPC 136/256; 65/99.2; 501/11

(57) ABSTRACT

A method for producing a glass substrate includes (a) a step of forming molten glass having a temperature T2 less than or equal to 1500° C. on molten tin having an iron concentration greater than or equal to 100 ppm to produce a glass ribbon having a temperature T4 less than or equal to 1100° C. and a logarithm log ρ greater than or equal to 8.8, and (b) a step of cooling the glass ribbon to room temperature to produce the glass substrate. The temperature T2 represents a temperature when a logarithm of a viscosity η (dPa·s) is 2, the temperature T4 represents a temperature when the logarithm of the viscosity η (dPa·s) is 4, and the logarithm log ρ represents a logarithm of a volume resistivity ρ (Ω·cm) at 150° C.

### CROSS-REFERENCE TO RELATED APPLICATION

The present application is a continuation application filed under 35 U.S.C. 111(a) claiming benefit under 35 U.S.C. 120 and 365(c) of PCT International Application No. PCT/JP2012/083117 filed on Dec. 20, 2012 and designating the U.S., which claims priority to Japanese Patent Application No. 2011-286738 filed on Dec. 27, 2011. The entire contents of the foregoing applications are incorporated herein by reference.

### BACKGROUND OF THE INVENTION

1. Field of the Invention

The present invention relates to a glass substrate and a method for producing a glass substrate.

2. Description of the Related Art

The so-called “high transmittance glass substrates” having high transmittance are used as glass substrates for solar batteries, for example.

Glass substrates may be produced in an industrial setting using the so-called float process. The float process involves producing a glass substrate by introducing molten glass into a float bath, which accommodates molten tin under a reducing atmosphere, forming a glass ribbon on the molten tin surface, and cooling the glass ribbon to room temperature. In this case, tin ions intrude upon the surface of the glass ribbon that comes into contact with the molten tin (referred to as “bottom face” hereinafter) through thermal diffusion such that strong reducing conditions are created at the outermost surface. Also, in a case where the iron concentration within glass and the iron concentration within tin are not in a state of equilibrium, iron diffusion occurs in the direction toward equilibrium. As a result, in a case where the iron concentration within the molten tin is lower than the tin concentration within the glass ribbon, the iron concentration within the molten tin increases until reaching equilibrium. On the other hand, in a case where the iron concentration within the molten tin is higher than the tin concentration within the glass ribbon, the iron concentration within the glass ribbon decreases until reaching equilibrium.

In the case of producing the “high transmittance glass substrate” using the float process, attention needs to be directed to the intrusion of iron components from the molten tin side to the glass ribbon side at the bottom face. This is because iron components exhibit light absorbing properties when residing within glass under an ion state. For example, divalent iron ions have an absorption peak at a wavelength around 1000 nm. Trivalent iron ions have an absorption peak at a wavelength around 380 nm. In addition, under strong reducing conditions, iron ions are known to exhibit strong coloration (amber coloration) having a peak at 450 nm. Accordingly, when such iron ions are contained in the glass ribbon, transmittance of the resulting glass substrate may be degraded. Notably, when a high concentration of iron components intrude upon the glass ribbon, it may become difficult to produce the “high transmittance glass substrate” itself.

In light of the above, Japanese Patent No. 4251552 (referred to as “Patent Document 1” hereinafter) discloses forming a “high transmittance glass substrate” using low-iron molten tin having an iron concentration that is greater than or equal to 55 ppm and less than 100 ppm.

According to the method disclosed in Patent Document 1, a “high transmittance glass substrate” is produced by using molten tin having a low iron concentration to prevent intrusion of iron from the molten tin side to the glass ribbon side.

However, the above method may not be considered a practical solution owing to the following reasons.

Generally, multiple types of glass substrates are produced using the same float process equipment. For example, a glass substrate for a glass member of a vehicle (characterized by having a relatively high iron concentration) and a high transmittance glass substrate are often produced using the same float process equipment. Because a glass substrate for a glass member of a vehicle often has a relatively high iron concentration, the amount of iron contained within molten tin after producing the glass substrate for the glass member of a vehicle may exceed 100 ppm, for example.

Thus, in the case of implementing the method disclosed in Patent Document 1, after producing the glass substrate for the glass member of a vehicle, the molten tin within the float bath has to be replaced with molten tin having a lower iron concentration in the case of producing a high transmittance glass substrate using the same equipment, for example. Replacing molten tin in this manner may lead to a decrease in the equipment operation rate and an increase in costs, for example.

Thus, there is still a demand for a technique for producing a high transmittance glass substrate while preventing the intrusion of iron components from the molten tin side to the glass ribbon side.

In light of the above, it is an object of the present invention to provide a glass substrate production technique for effectively preventing the intrusion of iron components even when molten tin having a relatively high iron concentration is used in a float process.

### SUMMARY OF THE INVENTION

According to one embodiment of the present invention, there is provided a glass substrate that is formed on molten tin having an iron concentration that is higher than an equilibrium concentration for achieving equilibrium with a glass to be produced. The glass substrate comprising glass material having a logarithm log ρ greater than or equal to 8.8, where the logarithm log ρ represents a logarithm of a volume resistivity ρ (Ω·cm) at 150° C.; a temperature T4 less than or equal to 1100° C., where the temperature T4 represents a temperature when a logarithm of a viscosity η (dPa·s) is 4; and a temperature T2 less than or equal to 1500° C., where the temperature T2 represents a temperature when the logarithm of the viscosity η (dPa·s) is 2.

According to another embodiment of the present invention, a method for producing a glass substrate is provided that includes: (a) a step of forming molten glass having a temperature T2 less than or equal to 1500° C. on molten tin having an iron concentration greater than or equal to 100 ppm to produce a glass ribbon having a temperature T4 less than or equal to 1100° C. and a logarithm log ρ greater than or equal to 8.8, where the temperature T2 represents a temperature when a logarithm of a viscosity η (dPa·s) is 2, the temperature T4 represents a temperature when the logarithm of the viscosity η (dPa·s) is 4, and the logarithm log ρ represents a logarithm of a volume resistivity ρ (Ω·cm) at 150° C.; and (b) a step of cooling the glass ribbon to room temperature to produce the glass substrate.

### BRIEF DESCRIPTION OF THE DRAWINGS

FIG. 1 is a flowchart illustrating an exemplary flow of a method for producing a glass substrate according to an embodiment of the present invention; and

FIG. 2 illustrates an exemplary configuration of a solar battery including the glass substrate according to the embodiment.

### DESCRIPTION OF THE PREFERRED EMBODIMENTS

In the following, a mode for carrying out the present invention will be described with reference to the drawings. Note, however, that the present invention is not limited to the embodiments described below but may include numerous variations and modifications that may be made without departing from the scope of the present invention.

A glass substrate according to one embodiment of the present invention may be a glass substrate having high transmittance that may be used as a substrate for a solar battery, for example.

A method for producing a glass substrate according to an embodiment of the present invention is characterized by including:

(a) a step of forming molten glass having a temperature T2 less than or equal to 1500° C. on molten tin having an iron concentration greater than or equal to 100 ppm to produce a glass ribbon having a temperature T4 less than or equal to 1100° C. and a logarithm log ρ greater than or equal to 8.8, where the temperature T2 represents a temperature when the logarithm of the viscosity η (dPa·s) of the molten glass is 2 (simply referred to as “T2” hereinafter), the temperature T4 represents a temperature when the logarithm of the viscosity η (dPa·s) of the glass ribbon is 4 (simply referred to as “T4” hereinafter), and the logarithm log ρ represents the logarithm of the volume resistivity ρ (Ω·cm) of the glass ribbon at 150° C.; and

(b) a step of cooling the glass ribbon to room temperature to produce a glass substrate.

As described above, in the known method, the iron concentration within the molten tin is controlled to be greater than or equal to 55 ppm and less than 100 ppm to prevent the intrusion of iron from the molten tin side to the glass ribbon side in producing a high transmittance glass substrate.

However, such a method has limited applicability to currently adopted general industrial methods for producing glass substrates. For example, in a case where a glass substrate for a glass member of a vehicle (characterized by having a relatively high iron concentration) and a high transmittance glass substrate are produced using the same equipment, the amount of iron contained within molten tin may often exceed 100 ppm, for example. If the molten tin within the float bath is to be replaced with molten tin having a lower iron concentration each time a high transmittance glass substrate is to be produced, the equipment operation rate may be decreased and costs may be increased, for example.

In this respect, the present embodiment is characterized by having the molten glass prepared such that log ρ of the glass ribbon may be greater than or equal to 8.8. Also, the present embodiment is characterized by having the molten glass prepared such that T4 may be less than or equal to 1100° C.

Note that in the present embodiment, the volume resistivity ρ represents a value measured in accordance with the ASTM C657-78 method.

Also, in the present embodiment, T4 represents a value measured by a rotational viscometer. Normally, the logarithm of the viscosity η (dPa·s) of glass is equal to 4 when the glass transitions from a molten state to a molding process in a tin bath. Thus, T4 corresponds to the temperature of the glass ribbon when it comes into contact with the molten tin.

Inventors of the present invention have found that when log ρ of the glass ribbon is greater than or equal to 8.8, movement of various types of ions from the molten tin side to the glass ribbon side may be effectively prevented and high diffusion prevention characteristics can be achieved. Accordingly, in the present embodiment, intrusion of iron components and tin components from the molten tin side to the glass ribbon side may be effectively prevented even when the glass ribbon comes into contact with molten tin. That is, in the present embodiment, intrusion of iron components from the molten tin side to the glass ribbon side may be effectively prevented even when the concentration of iron contained in the molten tin is greater than or equal to 100 ppm.

Also, in the present embodiment, T4 is arranged to be less than or equal to 1100° C. That is, the temperature of the glass ribbon when it comes into contact with the molten tin is controlled to be less than or equal to 1100° C. Thus, reactivity between the glass ribbon and the molten tin may be controlled, and intrusion of iron components from the molten tin side to the glass ribbon side may be further prevented.

Further, the present embodiment is characterized in that T2 of the molten glass is arranged to be less than or equal to 1500° C.

Note that T2 represents a value measured by a rotational viscometer.

Generally, an equilibrium reaction between divalent iron (ions) and trivalent iron (ions) may be expressed by the following formula (1).

Fe₂O₃=2FeO+½O₂ (1)

This equilibrium tends to shift to the right side as the temperature increases.

In this case, visible light transmittance Tv is known to decrease as the amount of iron components (total amount of divalent iron ions and trivalent iron ions) contained within a glass substrate increases. Also, solar radiation transmittance Te is known to decrease as the amount of divalent iron ions contained in the glass substrate increases. Accordingly, in order to produce a “high transmittance glass substrate” having both high visible light transmittance Tv and high solar radiation transmittance Te, the amount of divalent iron ions contained within the glass substrate needs to be controlled in addition to controlling the total amount of iron components contained within the glass substrate.

As described above, in the present embodiment, the molten glass is prepared such that log ρ of the glass ribbon may be greater than or equal to 8.8 and T4 may be less than or equal to 1100° C.

Also, in the present embodiment, T2 of the molten glass is less than or equal to 1500° C. Accordingly, in the present embodiment, progression of the reaction of formula (1) in the right side direction may be controlled, and even when a slight amount of iron components are contained within the glass substrate, the amount of divalent iron ions affecting the solar radiation transmittance Te may be controlled.

Thus, in the present embodiment, a “high transmittance glass substrate” having both high visible light transmittance Tv and high solar radiation transmittance Te may be produced.

As can be appreciated, in the present embodiment, a high transmittance glass substrate having high transmittance may be produced using a general float process equipment without having to pay attention to the concentration of iron contained in the molten tin.

Also, in the method for producing a glass substrate according to the present embodiment, glass having a volume resistivity ρ such that log ρ is greater than or equal to 8.8 is produced, and T4 of the molten glass is arranged to be less than or equal to 1100° C.

In this case, in addition to preventing the intrusion of iron components contained in the molten tin, the molten tin itself may be effectively prevented from intruding into the glass ribbon side.

For example, one undesired phenomenon resulting from performing a thermal process on the glass substrate includes the development of haze on the surface of the glass substrate referred to as “bloom”. Such a phenomenon occurs when excessive tin ions are diffused on the bottom face of the glass substrate such that a tin-rich layer is formed. That is, because the tin-rich layer and the glass substrate bulk side have different thermal expansion coefficients, when the glass substrate including the tin-rich layer is thermally processed, haze may appear on the tin-rich layer as a result of the mismatch in thermal expansion behaviors.

In the method according to the present embodiment, glass having a volume resistivity ρ such that log ρ is greater than or equal to 8.8 is produced. Also, T4 of the molten gas is arranged to be less than or equal to 1100° C. Accordingly, tin may be effectively prevented from intruding into the glass ribbon side from the surface of the glass ribbon that comes into contact with the molten tin. Thus, the method according to the present embodiment has an additional advantageous effect of preventing the so-called bloom phenomenon.

(Method for Producing Glass Substrate of Present Embodiment)

In the following, the method for producing a glass substrate according to the present embodiment is described in greater detail.

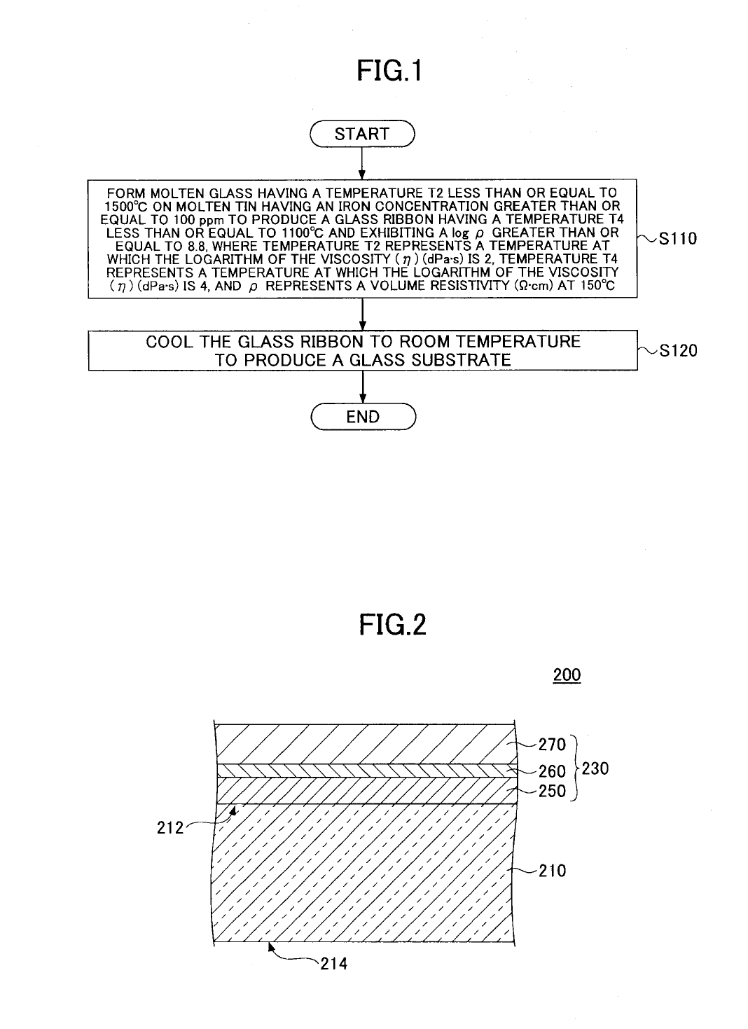

FIG. 1 schematically illustrates an exemplary flow of the method for producing a glass substrate according to the present embodiment.

As illustrated in FIG. 1, the method for producing a glass substrate according to the present embodiment includes:

(a) a step of forming molten glass having a temperature T2 less than or equal to 1500° C. on molten tin having an iron concentration greater than or equal to 100 ppm to produce a glass ribbon having a temperature T4 less than or equal to 1100° C. and a logarithm log ρ greater than or equal to 8.8, where the temperature T2 represents a temperature when the logarithm of the viscosity η (dPa·s) of the molten glass is 2, the temperature T4 represents a temperature when the logarithm of the viscosity η (dPa·s) of the glass ribbon is 4, and the logarithm log ρ represents the logarithm of the volume resistivity ρ (Ω·cm) of the glass ribbon at 150° C. (step S110); and

(b) a step of cooling the glass ribbon to room temperature to produce a glass substrate (step S120).

The above steps are described in detail below.

(Step S110)

First, a glass raw material to be used as the material for molten gas is prepared.

The glass raw material includes a glass base composition raw material, a cullet, and a refining agent. The refining agent may be, for example, SO₃, SnO₂, and/or Sb₂O₃.

The glass raw material is prepared such that T2 of the molten glass may be less than or equal to 1500° C. Also, the glass raw material is prepared such that T4 of the glass ribbon may be less than or equal to 1100° C. and log ρ of the glass ribbon may be greater than or equal to 8.8.

Note that although the method of preparing such glass raw material is not particularly limited, as one example, the glass raw material may be prepared in the manner described below.

For example, materials such as K₂O, BaO, and/or SrO may be added to the glass base composition raw material, and the amount at which the materials are added may be controlled to produce a glass substrate having the above-described characteristics. In one specific example, K₂O, BaO, and/or SrO may be added to the glass base composition raw material such that the concentration of K₂O, BaO, and/or SrO within the glass substrate exceeds the concentration at which the K₂O, BaO, and/or SrO may exist as unavoidable impurities. By adding appropriate amounts of K₂O, BaO, and/or SrO, log ρ of the glass may be increased, the glass in the molten glass state and the glass ribbon state may be maintained at a relatively low viscosity, and T2 and T4 may be decreased.

The K₂O, BaO, and/or SrO (total concentration of K₂O+BaO+SrO) may be included at an oxide-based mass ratio of at least 1 mass %, and more preferably at least 1.5 mass %, with respect to the glass raw material. By arranging the concentration to be in the above range, the glass raw material may be stably adjusted such that log ρ may be greater than or equal to 8.8.

Also, the K₂O, BaO, and/or SrO (total concentration of K₂O+BaO+SrO) may be included at an oxide-based mass ratio of no more than 7 mass %, and more preferably no more than 5 mass %, with respect to the glass raw material. By arranging the concentration to be in the above range, T2 may be maintained within the desired temperature range, for example.

Note that the “oxide-based mass ratio” refers to the composition of various components contained in glass expressed as an oxide mass ratio, assuming all oxides and combined salts used in the glass raw material of the present embodiment are decomposed and turned into oxides upon being melted.

Next, the glass raw material prepared in the above manner is melted to form molten glass. The melting temperature depends on the glass raw material. For example, in the case where soda-lime-silica glass is used, the melting temperature may be approximately 1300° C. to approximately 1600° C.

Next, the molten glass is introduced into a float bath chamber that is under a controlled atmosphere. Normally, the atmosphere of the float bath chamber is controlled to a reducing atmosphere including hydrogen. A bath filled with molten tin (molten tin bath) is arranged in the float bath chamber. In the present embodiment, the iron concentration of the molten tin may be greater than or equal to 100 ppm; that is, the iron concentration may exceed 100 ppm such as 150 ppm or greater.

The molten glass introduced into the float bath chamber is formed into a glass ribbon on the molten tin surface.

In the present embodiment, the glass ribbon is formed such that log ρ may be greater than or equal to 8.8. In this way, iron components may be effectively prevented from intruding into the glass ribbon side from the surface of the glass ribbon that comes into contact with the molten tin.

Also, in the present embodiment, T4 is arranged to be less than or equal to 1100° C. That is, the temperature of the glass ribbon upon coming into contact with the molten tin is controlled to be less than or equal to 1100° C. In this way, reaction between the glass ribbon and the molten tin may be suppressed, and intrusion of iron components and tin components from the molten tin side may be further prevented.

Further, in the present embodiment, molten glass having the temperature T2 less than or equal to 1500° C. is used. In this way, even in a case where iron components intrude into the glass ribbon, the amount of divalent iron ions within the glass ribbon may be effectively controlled.

As can be appreciated from the above, inventors of the present invention have found that iron components and tin components can be effectively prevented from intruding and diffusing into the glass ribbon side by adjusting the properties of the glass raw material such that log ρ of the glass ribbon may be greater than or equal to 8.8, T4 may be less than or equal to 1100° C., and T2 may be less than or equal to 1500° C.

(Step S120)

Next, the glass ribbon formed in step S110 is discharged from the float bath chamber and is cooled to room temperature. In this way, the glass substrate of the present embodiment may be produced.

In the method for producing a glass substrate according to the present embodiment, iron components may be effectively prevented from intruding into the glass substrate, and the amount of divalent iron ions within the glass substrate may be effectively controlled. Accordingly, the glass substrate obtained by implementing the method of the present embodiment may have high transmittance.

(Glass Substrate of Present Embodiment)

The glass substrate of the present embodiment may be produced in the manner described above, for example. Note, however, that the glass substrate of the present embodiment may also be produced through other methods.

The glass substrate of the present embodiment is characterized by:

being formed on molten tin having an iron concentration that is greater than an equilibrium concentration for achieving equilibrium with the glass to be produced (e.g. molten tin having an iron concentration greater than or equal to 100 ppm);

having log ρ greater than or equal to 8.8;

having T2 less than or equal to 1500° C.; and

having T4 less than or equal to 1100° C.

In the glass substrate of the present embodiment, the concentration of iron components may be effectively controlled. Accordingly, in the glass substrate of the present embodiment, absorption at the wavelength of 1000 nm caused by divalent iron ions may be effectively prevented. Also, absorption at the wavelength of 450 nm caused by amber coloration may be effectively prevented. In this way, the glass substrate of the present embodiment may have high transmittance.

In the glass substrate of the present embodiment, log ρ of the glass substrate may be arranged to be within a range greater than or equal to 8.8 and less than or equal to 12.0.

Also, in the glass substrate of the present embodiment, T2 may be arranged to be within a range greater than or equal to 1350° C. and less than or equal to 1500° C.

Further, in the glass substrate of the present embodiment, T4 may be arranged to be within a range greater than or equal to 900° C. and less than or equal to 1100° C.

Note that the composition of the glass substrate of the present embodiment is not particularly limited as long as the glass substrate is adjusted to have the above-described characteristics. As one example, the glass substrate of the present embodiment may have a composition as indicated in the following Table 1, which represents the oxide mass ratios of various components.

TABLE 1

| COMPOSITION | mass % |
|---|---|
| SiO₂ | 68~75 |
| Al₂O₃ | 0~2.5 |
| CaO | 0~15 |
| MgO | 0~12 |
| Na₂O | 5~20 |
| K₂O | 0.8~5 |
| SrO | 0~1 |
| BaO | 0~1 |
| K₂O + SrO + BaO | 1.1~7 |
| Fe₂O₃ (TOTAL IRON) | 0~0.06 |

As further examples, the glass substrate of the present embodiment may have a composition as represented in Table 2 or Table 3 below.

TABLE 2

| COMPOSITION | mass % |
|---|---|
| SiO₂ | 69~74 |
| Al₂O₃ | 0.3~2.3 |
| CaO | 3~12 |
| MgO | 1~10 |
| Na₂O | 7~17 |
| K₂O | 1.0~4.5 |
| SrO | 0.1~0.8 |
| BaO | 0.1~0.8 |
| K₂O + SrO + BaO | 1.5~6 |
| Fe₂O₃ (TOTAL IRON) | 0~0.05 |

TABLE 3

| COMPOSITION | mass % |
|---|---|
| SiO₂ | 69.3~73 |
| Al₂O₃ | 0.5~2.1 |
| CaO | 5~10 |
| MgO | 3~8 |
| Na₂O | 9~15 |
| K₂O | 1.3~4.0 |
| SrO | 0.2~0.7 |
| BaO | 0.2~0.7 |
| K₂O + SrO + BaO | 2~5 |
| Fe₂O₃ (TOTAL IRON) | 0~0.03 |

Note that in the three types of compositions described above, at least a part of K₂O may be replaced by BaO and/or SrO, for example.

By arranging the composition of the glass substrate to have the composition ranges indicated in Tables 1-3, glass characterized by having T2 less than or equal to 1500° C. and T4 less than or equal to 1100° C. may be stably produced.

(Application of Glass Substrate of Present Embodiment)

In the following, an exemplary application of the glass substrate according to the present embodiment is described.

The glass substrate of the present embodiment may be used as a substrate of a solar battery, for example. In the following, a solar battery including the glass substrate of the present embodiment is described with reference to FIG. 2.

FIG. 2 is a cross-sectional view illustrating an exemplary configuration of a solar battery 200 including the glass substrate of the present embodiment.

As illustrated in FIG. 2, the solar battery 200 includes a glass substrate 210 having a first surface 212 and a second surface 214, and a solar battery element 230 arranged on the first surface 212 of the glass substrate 210. Note that although not illustrated in FIG. 2, the solar battery 200 may further include an anti-reflection coating (not shown) arranged on the second surface 214 of the glass substrate 210.

The solar battery element 230 includes a transparent conductive layer (first electrode layer) 250, a photoelectric conversion layer (power generating layer) 260, and a back surface conductive layer (second electrode layer) 270 arranged in this order from the glass substrate 210 side.

The transparent conductive layer 250 may be formed by a layer having SnO₂ as a main component, a layer having ZnO as a main component, or a layer made of tin-doped indium oxide (ITO), for example. Of the above layers, a layer having SnO₂ as a main component may be particularly suitable in view of material costs, mass production capability, and the potential to minimize an impact on the photoelectric conversion layer (power generating layer) 260 when components of the transparent conductive layer 250 intrude into the photoelectric conversion layer (power generating layer) 260. Note that “main component” refers to a component contained at an oxide mass ratio of at least 90 mass %.

Examples of the layer having SnO₂ as a main component include a layer made of SnO₂, a layer made of fluorine doped tin oxide (FTO), and antimony doped tin oxide (ATO), for example.

The transparent conductive layer 250 may be formed by thermal decomposition, CVD (chemical vapor deposition), sputtering, vapor deposition, ion plating, and spraying, for example.

The thickness of the transparent conductive layer 250 is normally within a range of 200 nm to 1200 nm.

The photoelectric conversion layer (power generating layer) 260 is normally made of a semiconductor thin film. Examples of semiconductor thin films that may be used include an amorphous silicon based semiconductor thin film, a microcrystalline silicon based semiconductor thin film, a compound semiconductor (e.g. CdTe based semiconductor) thin film, and an organic semiconductor thin film. Also, two or more of the above semiconductor thin films may be layered to form the photoelectric conversion layer (power generating layer) 260.

The thickness of the photoelectric conversion layer (power generating layer) 260 may be 50 nm to 500 nm in the case where an amorphous silicon based semiconductor is used, 500 nm to 5000 nm in the case where a microcrystalline silicon based semiconductor is used, 500 nm to 6000 nm in the case where layers of an amorphous silicon based semiconductor and a microcrystalline semiconductor are used, 500 nm to 10 μm in the case where a CdTe (cadmium telluride) based semiconductor is used.

The back surface conductive layer 270 may be made of a material having no optical transparency, a material having optical transparency, or layers of the above materials. Examples of a material having no optical transparency include silver and aluminum. Examples of a material having optical transparency include ITO, SnO₂, and ZnO. In the case of using a an optically transparent material as the back surface conductive layer 270, an anti-reflection layer may be arranged on the surface of the back surface conductive layer 270 opposite the photoelectric conversion layer 260, for example. Note that materials such as silver, aluminum, an alloy thereof, or white ink may be used as the anti-reflection layer, for example.

The thickness of the back surface conductive layer 270 is normally in the range of 100 nm to 10 μm.

In the present example, the glass substrate of the present embodiment is used as the glass substrate 210 of the solar battery 200.

As described above, in the glass substrate 210 of the present embodiment, the concentration of iron components may be effectively controlled so that the glass substrate may have high transmittance. That is, in the glass substrate 210, absorption of light particularly in the wavelength range of approximately 1000 nm may be effectively prevented. In this way, the solar battery 200 including the glass substrate 210 of the present embodiment may achieve improved efficiency, for example.

Note that a solar battery using the glass substrate of the present embodiment is not limited to the solar battery 200 as described above. For example, the glass substrate of the present embodiment may also be used in a CIGS (copper indium gallium selenide) based compound solar battery, a crystalline silicon based solar battery, and a glass encapsulated thin film solar battery cover glass.

### WORKING EXAMPLES

In the following, working examples of the present embodiment are described.

### Working Example 1

In the present example, two types of glass substrates (glass substrates A and B) with different values for log ρ were produced by implementing the float process using a tin bath having an iron concentration of approximately 150 ppm. Further, the transmittance of the glass substrates A and B were evaluated.

(Glass Substrate Production)

The glass substrates A and B were arranged to have the composition of the soda-lime-silica glass as represented by the above Table 1. The target thicknesses of the glass substrates A and B were both arranged to be 3.9 mm.

Note that the volume resistivity ρ of the glass substrates A and B were measured in accordance with the ASTM C657-78 method as described below.

First, the glass substrate subject to evaluation was cut into a sample having dimensions of approximately 50 mm in height and approximately 50 mm in width. Further, both faces of the sample were optically polished to obtain a thickness of approximately 3.5 mm.

Next, metal aluminum films were formed on both sides of the sample using the vapor deposition method. The metal aluminum films were used as electrodes to measure the volume resistivity of the sample under three different temperature conditions of 100° C., 150° C., and 300° C.

The measurement results obtained by measuring the volume resistivity of the sample at the above measurement temperatures were plotted against the reciprocals of the measurement temperatures. Based on the slope A and intercept B of the resulting line, the logarithm of the volume resistivity ρ (Ω·cm) was calculated using the following formula (2).

log ρ=A/T+B (2)

The following Table 4 indicates the glass composition, T4, T2, and the logarithm log ρ of the glass substrates A and B.

TABLE 4

| | | | | | | | | LOGARITHM | | | | |
|---|---|---|---|---|---|---|---|---|---|---|---|---|
| | | | | | | | | OF VOLUME | | | TRANSMITTANCE | |
| | | | | | | | | RESISTIVITY | | | WAVE- | WAVE- |
| GLASS | GLASS COMPOSITION (wt %) | | | | | | | ρ (Ωcm) | T4 | T2 | LENGTH | LENGTH |
| SUBSTRATE | SiO₂ | Al₂O₃ | CaO | MgO | Na₂O | K₂O | Fe₂O₃ | log ρ | (° C.) | (° C.) | 450 nm | 1000 nm |
| A | 71.06 | 1.91 | 7.70 | 5.19 | 12.35 | 1.53 | 0.008 | 8.92 | 1045 | 1466 | 91.05 | 90.08 |
| B | 71.32 | 1.89 | 7.49 | 5.04 | 13.91 | 0.05 | 0.008 | 8.23 | 1034 | 1455 | 90.80 | 89.80 |

(Glass Substrate Transmittance Evaluation)

Next, the above two types of glass substrates A and B were used to measure their transmittance at the wavelength 450 nm and the wavelength 1000 nm. Generally, amber coloration has an absorption peak at a wavelength of around 450 nm. Also, divalent iron ions have an absorption peak at a wavelength of around 1000 nm. The above two absorption coefficients are comparatively greater than the absorption coefficient of trivalent iron ions, which has an absorption peak at around a wavelength of 380 nm. Thus, by evaluating the transmittance at the above two wavelengths 450 nm and 1000 nm, an overall transparency of the glass substrate may be determined to some extent.

Note that the transmittance was measured by preparing samples of the glass substrates A and B by arranging the glass substrates into 40×40 mm plates and measuring the samples using a spectrophotometer (LAMBDA 950 by PerkinElmer Inc.).

The results of the measurement are indicated in the “Transmittance” column of the above Table 4.

As can be appreciated from these measurement results, the glass substrate A exhibiting a value of log ρ greater than 8.8 has a higher transmittance compared to the transmittance of the glass substrate B exhibiting a value of log ρ less than 8.8.

According to the present example, a glass substrate with a value of log ρ greater than or equal to 8.8 may be obtained by controlling the concentration of K₂O within the glass substrate. Also, the values of T2 and T4 may be maintained within their respective desired ranges. Further, the glass substrate having the above characteristics can achieve high transmittance at both of the wavelengths 450 nm and 1000 nm.

That is, by arranging log ρ of the glass substrate to be greater than or equal to 8.8, arranging T4 to be less than or equal to 1100° C., and arranging T2 to be less than or equal to 1500° C., intrusion of iron components into the glass ribbon may be prevented during production of the glass substrate, and in this way, the glass substrate may achieve high transmittance at the wavelengths 450 nm and 1000 nm.

### Working Example 2

In the present example, a measurement sample was created by depositing a transparent conductive layer on one surface of a glass substrate, and the transmittance of the measurement sample at the wavelength 1000 nm was evaluated.

Note that the glass substrates A and B used in the above Working Example 1 were used to create the measurement sample in the present example. That is, measurement samples were obtained by depositing a tin oxide layer on one surface of each of the glass substrates A and B by implementing a general CVD process. In the following descriptions, the measurement sample including the glass substrate A is referred to as “measurement sample A”, and the measurement sample including the glass substrate B is referred to as “measurement sample B”. The thickness of the tin oxide layer was arranged to be approximately 500 nm. Note that the method for measuring the transmittance used in the present example was the same as that used in the above Working Example 1.

The measurement results obtained by measuring the transmittance in the present example indicated that for the measurement sample A, the transmittance at wavelength 1000 nm was 83.7%. On the other hand, for the measurement sample B, the transmittance at wavelength 1000 nm was 83.3%.

As can be appreciated from the above measurement results, even in the case where the glass substrates A and B are arranged into measurement samples by depositing conductive layers thereon, a higher transmittance may still be achieved by the measurement sample A compared to the measurement sample B.

### Working Example 3

In the present example, the measurement samples A and B prepared in the above Working Example 2 were used to conduct a DHB (Dump Heat Bias) test.

In the DHB test, electrical and thermal durability of the transparent conductive layer can be evaluated at the same time.

The DHB test was conducted in the following manner.

First, the measurement sample A (or measurement sample B) was heated to a temperature within a range of 50° C. to 200° C. Note that although DHB test procedures implemented on the measurement sample A are described below, the same procedures were implemented on the measurement sample B.

Next, while maintaining the measurement sample A in the heated state, an external power supply was used to apply a voltage of 500 V to the measurement sample A. The voltage was applied to the measurement sample A for 15 minutes in a manner such that the glass substrate side of the measurement sample A constitutes the positive (anode) side and the transparent conductive layer side constitutes the negative (cathode) side.

Next, after stopping the heating and voltage application, the measurement sample A was arranged inside a constant-temperature bath where the temperature and humidity are controlled, and an exposure test was conducted on the measurement sample A. The humidity within the constant-temperature bath was controlled to a relative humidity of 100%, and the temperature within the constant-temperature bath was controlled to be 50° C. The exposure was conducted for one hour.

After the exposure test, appearance observations were made on the measurement sample A to evaluate whether exfoliation of the transparent conductive layer has occurred. Note that in this evaluation, the occurrence of exfoliation at the corresponding temperature was determined when exfoliation could be visually recognized from at least one portion of the measurement sample A.

The test results indicated that for the measurement sample A, no exfoliation occurred after the exposure test when the heating temperature upon voltage application was less than or equal to 150° C. On the other hand, the test results indicated that for the measurement sample B, exfoliation of the transparent conductive layer occurred when the heating temperature upon voltage application exceeded 120° C.

As can be appreciated from the above test results, stronger adhesion between the glass substrate and the transparent conductive layer may be achieved by the measurement sample A compared to the measurement sample B.

Also, based on the above test results, the adhesion between the glass substrate and the transparent conductive layer may presumably be maintained under harsher conditions by using the glass substrate of the present embodiment as opposed to the conventional glass substrate.

According to one aspect of the present embodiment, a method for producing a glass substrate may be provided that can effectively prevent the intrusion of iron even in a case where molten tin having a relatively high iron concentration is used in a float process. According to another aspect of the present embodiment, a glass substrate may be provided that is produced using molten tin having a relatively high iron concentration in a manner such that intrusion of iron may be effectively prevented.

The present embodiment may be applied to a high transmittance glass substrate that is required to have high transmittance such as a glass substrate of a solar battery.

Although the present invention has been described above with respect to certain illustrative embodiments and examples, the present invention is not limited to these embodiments and examples but includes numerous variations and modifications that may be made within the scope of the present invention.

What is claimed is:

1. A glass substrate that is formed on molten tin having an iron concentration that is higher than an equilibrium concentration for achieving equilibrium with a glass to be produced, the glass substrate comprising a glass material having:
a logarithm log ρ greater than or equal to 8.8, where the logarithm log ρ represents a logarithm of a volume resistivity ρ (Ω·cm) at 150° C.;
a temperature T4 less than or equal to 1100° C., where the temperature T4 represents a temperature when a logarithm of a viscosity η (dPa·s) is 4; and
a temperature T2 less than or equal to 1500° C., where the temperature T2 represents a temperature when the logarithm of the viscosity η (dPa·s) is 2.

2. The glass substrate according to claim 1, further comprising at least one material selected from a group including K₂O, BaO, and SrO at a concentration exceeding an unavoidable impurity concentration.

3. The glass substrate according to claim 2, wherein a total concentration of K₂O+BaO+SrO expressed as an oxide-based mass ratio is greater than or equal to 1 mass %.

4. The glass substrate according to claim 1, wherein the iron concentration of the molten tin is greater than or equal to 100 ppm.

5. The glass substrate according to claim 1, further comprising a transparent conductive oxide layer.

6. A method for producing a glass substrate comprising:
(a) a step of forming molten glass having a temperature T2 less than or equal to 1500° C. on molten tin having an iron concentration greater than or equal to 100 ppm to produce a glass ribbon having a temperature T4 less than or equal to 1100° C. and a logarithm log ρ greater than or equal to 8.8, where the temperature T2 represents a temperature when a logarithm of a viscosity η (dPa·s) is 2, the temperature T4 represents a temperature when the logarithm of the viscosity η (dPa·s) is 4, and the logarithm log ρ represents a logarithm of a volume resistivity ρ (Q cm) at 150° C.; and
(b) a step of cooling the glass ribbon to room temperature to produce the glass substrate.
